(19) United States
(12) Patent Application Publication
(10) Pub. No.: US 2004/0192050 A1
(43) Pub. Date: Sep. 30, 2004

(54) Method for etching semiconductor substrate

(75) Inventor: Shuichi Yamashita, Kariya-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/802,721

(22) Filed: Mar. 18, 2004

(30) Foreign Application Priority Data
Mar. 24, 2003 (JP) 2003-79976

(51) Int. Cl. H01L 21/311

(52) U.S. Cl. 438/695

(57) ABSTRACT

A silicon substrate is immersed in potassium hydroxide solution. Then, a main surface of the silicon substrate, which is immersed in the potassium hydroxide solution, is anodized by applying an electrical potential to the silicon substrate while the silicon substrate is used as an anode, so that an oxide film is formed in the main surface of the silicon substrate. Then, a main surface side of the silicon substrate is etched in the potassium hydroxide solution.

### CROSS REFERENCE TO RELATED APPLICATION

This application is based on and incorporates herein by reference Japanese Patent Application No. 2003-79976 filed on Mar. 24, 2003.

### BACKGROUND OF THE INVENTION

1. Field of the Invention

The present invention relates to a method for etching a semiconductor substrate by immersing the semiconductor substrate in etching solution. More particularly, the present invention relates to an etching method for forming a diaphragm, which is a thin wall part, in the semiconductor substrate used as, for example, a pressure sensor, an acceleration sensor, a gas sensor or a flow sensor.

2. Description of Related Art

According to a previously propose technique, a silicon diaphragm of a semiconductor pressure sensor or of a semiconductor acceleration sensor may be formed by covering a main surface of the silicon substrate with an etching mask consisting of a SiO₂ or SiN film that resists etching, and then by wet etching the silicon substrate using etching solution, such as KOH solution.

As a result, a recess, which is recessed from the main surface of the silicon substrate, is formed at an area corresponding with an opening in the etching mask on the main surface of the silicon substrate. A base part of the recess turns into the thin wall part, which in turn becomes the diaphragm.

Here, silicon is etched using the KOH solution, and the KOH concentration and the temperature of the KOH solution are adjusted during the etching process. The KOH solution, which has a KOH concentration level of 30 weight percent, is generally used to provide smoothness in an etched surface (base part of the recess).

However, when the main surface of the silicon substrate is a (110) surface, the etched surface would have a characteristic surface roughness and would cause a difficulty in forming a smooth diaphragm. This surface roughness is believed to be caused by an etch rate anisotropy in the vicinity of the (110) surface.

The inventor of the present invention have studied the etching method of the previously proposed technique and discovered that the roughness on the etched surface, which is characteristic of the (110) surface, is dependent on the KOH concentration level in the etching solution. The etched surface exhibits striation when the KOH concentration level is less than or equal to 38 weight percent. The etched surface exhibits pyramid shaped patterns when the concentration level is greater than or equal to 40 weight percent.

The silicon diaphragm is formed with a prescribed thickness by removing most of the silicon substrate by etching down in a direction orthogonal to the main surface. For example, in order to achieve a precise pressure sensitivity characteristic in a semiconductor pressure sensor, the diaphragm thickness needs to be uniform. In other words, the base surface of the recess, which is the etched surface, must be smooth and flat.

Besides the above method that uses the KOH solution, Japanese Unexamined Patent Publication No. 8-13165 (corresponding to U.S. Pat. No. 5,650,043) discloses an alternative method of wet etching for obtaining a flat etched surface. In this method, the silicon substrate is immersed in, for example, ammonium fluoride (NH₄F) solution, and an electrical potential is applied to the silicon substrate during the etching process. The electrical potential is controlled to be smaller than or equal to a rest potential, so that this proposed method can provide an atomic order of flatness.

Japanese Unexamined patent Publication No. 2000-91307 discloses another method. In this method, tetramethyl ammonium hydroxide (TMAH) solution is used as the etching solution, and an electrical potential is applied to the silicon substrate during the etching process.

While the etching methods described in the above mentioned publication documents would ensure flat etched surfaces, the NH₄F solution and the TMAH solution, which are used as the etching solutions, offer smaller etch rates in comparison to that of the KOH solution and thus are not suitable for a semiconductor manufacturing process, in terms of productivity. Furthermore, the NH₄F solution contains fluorine ions and presents a safety concern.

### SUMMARY OF THE INVENTION

The present invention addresses the above disadvantages. Thus, it is an objective of the present invention to provide a semiconductor substrate etching method, which uses potassium hydroxide solution as etching solution and which improves smoothness of an etched surface.

To achieve the objective of the present invention, there is provided a method for etching a semiconductor substrate by immersing the semiconductor substrate in etching solution. In the method, a silicon substrate, which is the semiconductor substrate, is immersed in potassium hydroxide solution, which is the etching solution. Then, a main surface of the silicon substrate, which is immersed in the potassium hydroxide solution, is anodized by applying an electrical potential to the silicon substrate while the silicon substrate is used as an anode, so that an oxide film is formed in the main surface of the silicon substrate. Next, a main surface side of the silicon substrate is etched in the potassium hydroxide solution.

### BRIEF DESCRIPTION OF THE DRAWINGS

The invention, together with additional objectives, features and advantages thereof, will be best understood from the following description, the appended claims and the accompanying drawings in which:

FIG. 1 is a cross-sectional view of a semiconductor pressure sensor according to an embodiment of the present invention;

FIG. 2 is a schematic view showing an etcher used in an etching method of the embodiment;

FIG. 3A is a schematic plan view showing an etching mask formed on a silicon wafer, which is a silicon substrate used in the embodiment;

FIG. 3B is a cross sectional view showing the silicon wafer and the etching mask of FIG. 3A;

FIG. 4A is a cross-sectional view showing one stage of an etching process of the silicon wafer;

FIG. 4B is a cross-sectional view showing another stage of the etching process of the silicon wafer;

FIG. 4C is a cross-sectional view showing another stage of the etching process of the silicon wafer;

FIG. 5 is a diagram showing a surface roughness Rz of an etched surface; and

FIG. 6 is a diagram showing effects of changes in the KOH concentration level and temperature of the KOH solution on the surface roughness.

### DETAILED DESCRIPTION OF THE INVENTION

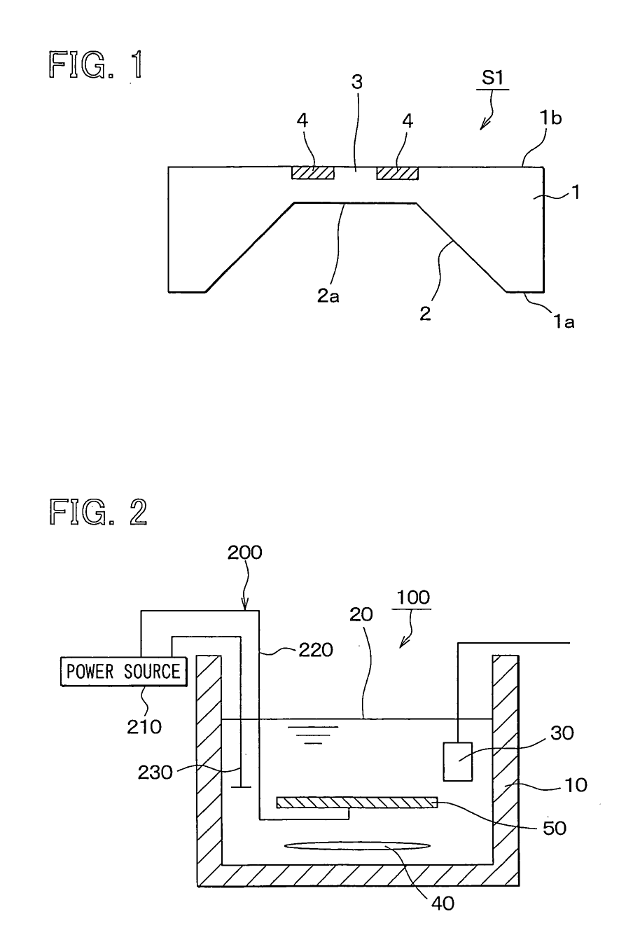

An embodiment of the present invention will be described with reference to the accompanying drawings. FIG. 1 is a diagram showing a cross-sectional outline of a semiconductor pressure sensor S1 according to the present embodiment. In FIG. 1, a numeral 1 indicates a silicon substrate, which serves as a semiconductor substrate. In the silicon substrate 1 of the present example, a surface orientation of each of first and second main surfaces 1a, 1b is (110).

In the first main surface 1a, which is one (lower one in FIG. 1) of the main surfaces 1a, 1b of the silicon substrate 1, a recess 2 is formed by a KOH etching process and is thus recessed from the first main surface 1a. A portion of the silicon substrate 1, in which a base surface 2a of the recess 2 is located, forms a thin wall part. The thin wall part is formed as a diaphragm 3 that is used for pressure measurement.

In the second main surface 1b, which is opposite from the first main surface 1a, a strain gauge 4 is formed in an area that corresponds to the diaphragm 3. The strain gauge 4 forms, for example, a bridge circuit and provides an electrical output signal that corresponds to a stress or strain generated as a result of a distortion in the diaphragm 3. The strain gauge 4 is formed as a diffused resistor formed by diffusion or ion implanting.

When the diaphragm 3 deforms under pressure in the semiconductor pressure sensor S1, a signal is outputted by the strain gauge 4 in response to the distortion resulting from the deformation in the diaphragm 3. The output signal from the strain gauge 4 passes through a wiring part and a pad part, which are not shown in the figure, and is outputted to, for example, an external signal processing circuit. The pressure is thus detected.

A method of manufacturing the semiconductor pressure sensor S1 will be described next. The semiconductor pressure sensor S1 is formed with a semiconductor manufacturing technology using the silicon substrate having the main surfaces, that are (110) surfaces. A method of etching the silicon substrate for forming the recess 2 will be described.

FIG. 2 shows a structural outline of an etcher 100 used for the present etching method. A numeral 10 indicates an etch bath, which is made of, for example, Teflon (registered trademark). The etch bath 10 holds potassium hydroxide (KOH) solution 20, which is etching solution. The KOH solution 20 is adjusted to have a KOH concentration in a range, which is preferably greater than or equal to 39 weight percent but is preferably less than or equal to 48 weight percent (i.e., preferably in the range of 39-48 weight percent).

The etcher 100 also has a temperature controller 30, which includes a temperature sensor and a heater. The temperature controller 30 heats or cools the KOH solution 20 to control the temperature of the KOH solution 20. The KOH solution 20 is held in a temperature range, which is preferably equal to or greater than 90 degrees Celsius but is preferably equal to or less than 140 degrees Celsius (i.e., preferably in the range of 90-140 degrees Celsius).

A stirrer 40 is placed inside at a bottom part of the etch bath 10. When placed under a rotating magnetic field, the stirrer 40 stirs the KOH solution 20 at a stirring rate that would create a uniform temperature distribution throughout the KOH solution 20.

The silicon substrate to be etched is a silicon wafer 50, which has first and second main surfaces 51, 52, which are (110) surfaces. The silicon wafer 50 is immersed in the KOH solution 20 in the etch bath 10 and is etched.

While only a single piece of the silicon wafer 50 is shown in FIG. 2, multiple silicon wafers can, of course, be etched simultaneously in a mass production process.

Furthermore, the etcher 100 includes an anodizing means 200 for forming an oxide film on the silicon wafer 50 using an anodizing process. The anodizing means 200 includes a direct current power source 210, an electrical potential applying electrode 220 and a reference electrode 230. The electrical potential applying electrode 220 is electrically connected to the silicon wafer 50, and the silicon wafer 50 is used as an anode. Thus, the electrical potential applying electrode 220 applies an electrical potential to the silicon wafer 50. The reference electrode 230 is made of platinum.

The anodizing means 200 is constructed to apply a desired voltage, which is set relative to an electrical potential of the reference electrode 230 immersed in the KOH solution 20, to the silicon wafer 50.

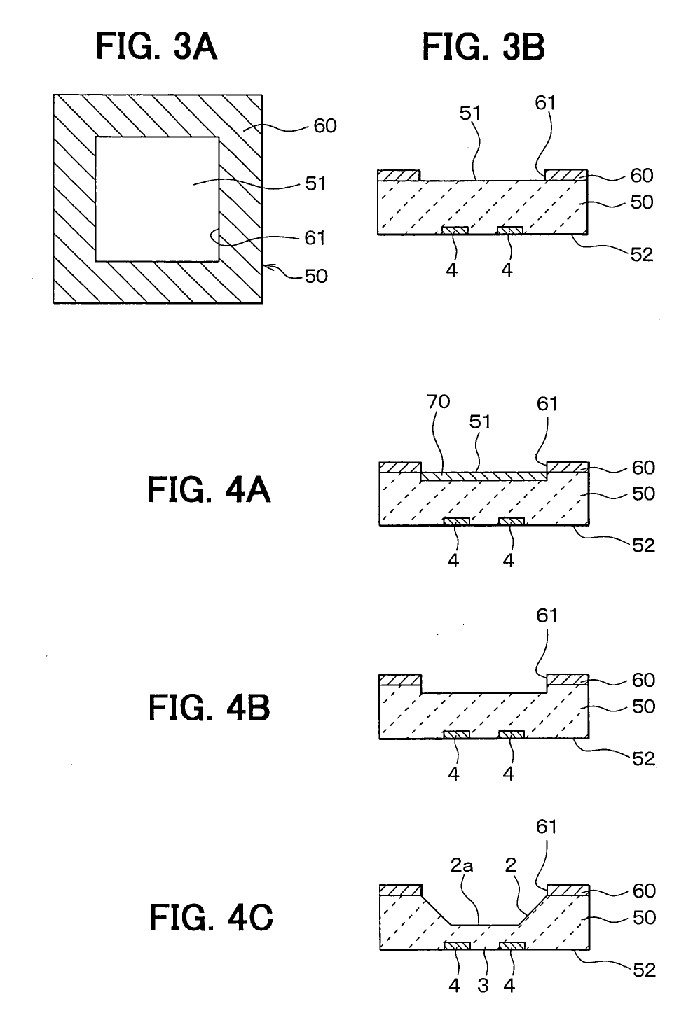

FIGS. 3A and 3B show an etching mask 60, which is used to form the diaphragm and is provided in the first main surface 51 of the silicon wafer 50. The silicon wafer 50, which is in the state shown in FIGS. 3A and 3B, is immersed into the KOH solution 20 and is etched.

The first main surface 51 of the silicon wafer 50 corresponds with the first main surface 1a of the silicon substrate 1 and is the surface that is to be etched for forming the recess 2. As shown in FIG. 3B, the strain gauge 4 is formed in the second main surface 52 of the silicon wafer 50.

In the first main surface 51 of the silicon wafer 50, which is the (110) surface, the etching mask 60 is formed to form the diaphragm 3 through etching.

The etching mask 60 is formed by depositing a film, which is a silicon nitride film that serves as an etch-resistant material, using, for example, a plasma CVD method, and then opening an area of the deposited film that is to be etched by, for example, a photolithography method. While FIG. 3A shows a square opening 61 in the etching mask 60, the opening can be of any shape or size.

Once the etching mask 60 is formed on the silicon wafer 50, the silicon wafer 50 is etched using the etcher 100 shown in FIG. 2. Although not shown in FIG. 2, the second main surface 52 and side surfaces of the silicon wafer 50 are masked in a manner that limits exposure of the second main surface 52 and the side surfaces of silicon wafer 50 to the KOH solution 20.

Then, the silicon wafer 50 is connected to the electrical potential applying electrode 220 of the anodizing means 200 and is immersed in the KOH solution 20. An electrical contact between the silicon wafer 50 and the electrical potential applying electrode 220 can be established, for example, as follows. First, a contact hole is formed in, for example, a part of the second main surface 52 of the silicon wafer 50. Then, the contact hole is filled with a conductive material, such as aluminum. Thereafter, the conductive material is masked in order to avoid exposure to the KOH solution 20. Thus, the silicon wafer 50 and the electrical potential applying electrode 220 are electrically connected to each other through the conductive material.

FIGS. 4A-4C show a process of the etching of the silicon wafer 50. Firstly, an electrical potential is applied from the direct current power source 210 to the silicon wafer 50, which is immersed in the KOH solution 20, in a manner that causes formation of an oxide film 70 by an anodizing process.

More specifically, in the anodizing process, the electrical potential, which is applied to the silicon wafer 50 immersed in the KOH solution 20, is set to be equal to or greater than a passivation potential. Here, the passivation potential is defined as an electrical potential, at which an anode current that flows through the silicon wafer 50 becomes maximum relative to the electrical potential of the reference electrode 230.

As a result, as shown in FIG. 4A, the silicon oxide film 70, which is the oxide film of the present invention, is formed on the first main surface 51 of the silicon wafer 50, which is exposed in the opening 61 of the etching mask 60. Then, the etching process on the first main surface 51 begins.

As described above, the silicon oxide film 70 is formed by the anodization at the beginning of the etching process. It is preferred that the application of the electrical potential to the silicon wafer 50 for creating the oxide film is kept for two minutes or longer at least at the beginning of the etching process. In this way, the silicon oxide film 70 can be formed appropriately. For example, the oxide film 70, which has a thickness of about 1 nm, is thus formed. The formation of the silicon oxide film 70 is confirmed by, for example, an analysis using the x-ray photoelectron spectroscopy (XPS) method.

Upon the initiation of the etching process on the first main surface 51 of the silicon wafer 50, the etching process is continued without applying the electrical potential to the silicon wafer 50, i.e., the etching process is continued while stopping the application of the electrical potential to the silicon wafer 50.

Then, as shown in FIG. 4B, the silicon oxide film 70, which is exposed in the opening 61 of the etching mask 60, is etched and removed by the KOH solution 20. As soon as the etching of the silicon oxide film 70 ends, a silicon part of the silicon wafer 50 is exposed, and a silicon etching process begins.

Although details of the process mechanism are not well understood, the following thing is conceivable. That is, when the etching process of the silicon is performed at the same time the etching process of the silicon oxide film 70 ends, the initial point of the etching process of the silicon becomes a hydrophilic surface. The formation of the hydrophilic surface allows initiation of uniform etching of the silicon.

The silicon wafer 50 is etched on the first main surface 51, and finally the recess 2 is formed, as shown in FIG. 4C. The resulting etched surface 2a, which is the base surface 2a of the recess 2, has a high degree of smoothness.

The diaphragm 3 is thus formed as the recess 2. Then, the etching mask 60 is selectively removed from the silicon wafer 50 by, for example, etching, so that the semiconductor pressure sensor S1 shown in FIG. 1 is formed.

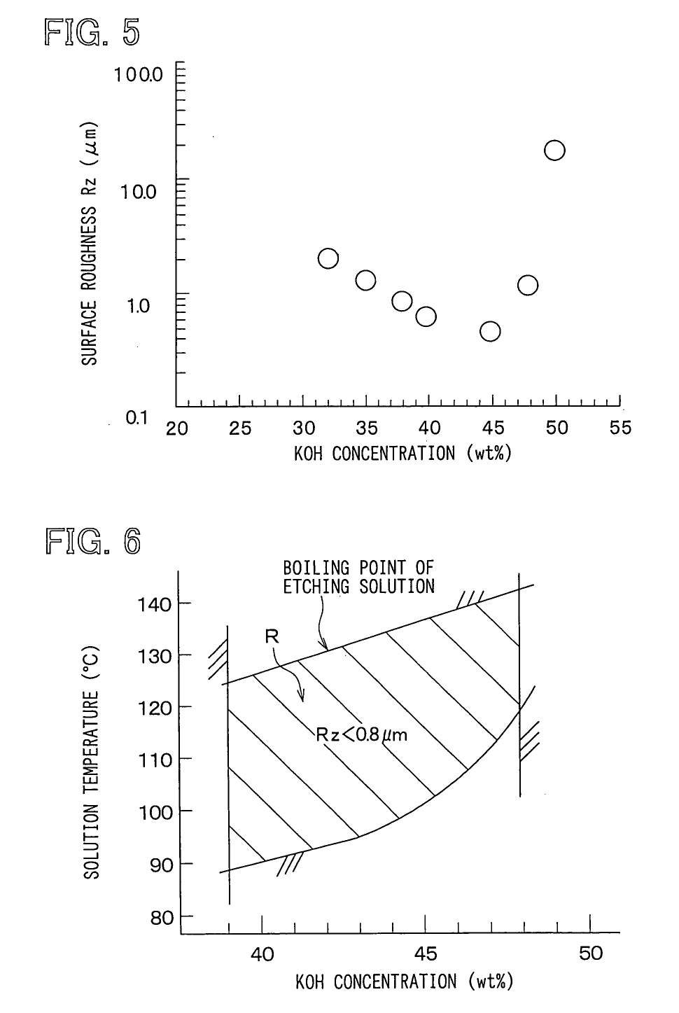

FIG. 5 shows an exemplary improvement in the smoothness of the etched surface 2a. FIG. 5 is a diagram showing how a roughness Rz of the etched surface 2a depends on the KOH concentration level. The result of FIG. 5 is obtained through an etching process, in which the temperature of the KOH solution 20 is maintained at 110 degrees Celsius by the temperature controller 30, and the silicon oxide film 70, which is approximately 1 nm in thickness, is formed by the anodizing process on the surface of the silicon wafer 50 to be etched.

As shown in FIG. 5, the surface roughness Rz of the etched surface 2a is dependent on the KOH concentration level in the KOH solution 20. In the present example, the surface roughness Rz becomes less than 0.8 μm when the KOH concentration level is in a range, which is equal to or greater than 39 weight percent but is equal to or less than 48 weight percent (i.e., in a range of 39-48 weight percent). The resulting smoothness of the etched surface 2a is acceptable for a practical use.

This level corresponds to a level that is achieved when the recess and the diaphragm are formed in a silicon substrate, which has the main surface with a surface orientation of (100) that allows easy achievement of a high degree of smoothness in the etched surface. This level ensures acceptable diaphragm characteristics.

FIG. 6 shows experimental results, which are obtained by changing the etching conditions, i.e., the KOH concentration and the temperature of the KOH solution 20 at the time of performing the etching process after formation of the silicon oxide film 70, which has a thickness of about 1 nm similar to the case of FIG. 5 and which is formed by the anodizing process performed on the silicon wafer 50.

As shown in FIG. 6, there is provided a Cartesian coordinates system, in which the KOH concentration (weight percent) is indicated on an abscissa axis, and the solution temperature (degrees Celsius) is indicated on an ordinate axis. An area R, which is a shaded area in FIG. 6, represents a range within which the etched surface 2a achieves a surface roughness Rz of less than 0.8 μm.

In the area R, an upper limit of the solution temperature is a boiling point of the KOH solution 20. Specifically, as long as the KOH concentration level and the temperature of the KOH solution 20 fall within the range represented by the area R, the surface roughness Rz of the etched surface 2a is suitable for practical use.

Therefore, in the etching method of the present embodiment, as shown by the area R of FIG. 6, in order to improve the smoothness of the etched surface, it is desirable to set the KOH concentration of the KOH solution 20 in the range, which is equal to or greater than 39 weight percent but is equal to or less than 48 weight percent, and to set the solution temperature in the range, which is equal to or greater than 90 degrees Celsius but is equal to or less than 140 degrees Celsius.

It should be noted that the KOH concentration level and the solution temperature are not limited to the above ones and can be changed to any other appropriate ones depending on a desired surface roughness of the etched surface as well as the size or dimensions of an area being etched.

The present embodiment provides the etching method, which can improve the smoothness of the etched surface through use of the KOH solution as the etching solution in comparison to the prior art.

In the silicon substrate, which has the oxide film on its surface, the surface shows hydrophilic property. The present embodiment uses the hydrophilic property to perform the uniform etching and thereby provides the smooth etched surface.

Based on the above fact, a similarly smooth etched surface can be alternatively obtained by forming an oxide film on the surface of the silicon substrate in advance of the etching, using a generic thermal oxidation or chemical vapor deposition method. The present embodiment, on the other hand, provides an even easier method of forming the oxide film, without requiring an additional step for forming the oxide film on the silicon substrate prior to etching, by relying on an anodizing phenomenon that takes place in the etching solution.

Furthermore, according to the present embodiment, the silicon substrate 1, which forms the semiconductor pressure sensor S1, is formed by the above etching method. More specifically, the silicon oxide film 70 is first formed by the anodizing process in the first main surface 51 of the silicon wafer 50 immersed in the KOH solution 20, and the etching process is performed on the first main surface 51 side of the silicon surface 50.

Although the first main surface 51, which is the surface of the silicon substrate 1 that is to be etched, has the (110) surface, the etched surface, which is the base surface 2a of the recess 2, advantageously achieves the surface roughness Rz of less than 0.8 μm. In other words, according to the present embodiment, the silicon substrate (the semiconductor substrate) 1 achieves the smooth etched surface, which has been difficult to achieve with the prior art, in which the (110) surface is KOH etched.

In the above etching method, the etching process is first started on the main surface 51 of the silicon wafer 50, on which the silicon oxide film 70 has been formed by the anodizing process, and then the etching process continues without applying the electrical potential on the silicon wafer 50. However, the etching process may also be performed while the electrical potential, which enables formation of the silicon oxide film 70, is kept applied to the silicon wafer 50 throughout the etching process.

Specifically, the electrical potential, which enables the anodization, can be kept applied to the silicon wafer 50 throughout the etching process, in which the silicon wafer 50 is immersed in the KOH solution 20. In such a case, on the first main surface 51 of the silicon wafer 50, the silicon oxide film 70 is formed and is also etched at the same time to form the recess 2.

Also in such an instance, it is expected that the silicon oxide film 70 formed on the first main surface 51 of the silicon wafer 50 maintains the hydrophilic property of the main surface 51, which is the surface being etched. Thus, uniformness of the etching rate in the etched surface is improved, and thereby the smooth etched surface 2a is obtained in the silicon wafer 50.

Furthermore in such an instance, studies have shown that the surface roughness Rz of the etched surface 2a would show a similar type of dependence on the KOH concentration level, as shown in FIG. 5, as well as on the etching conditions, as shown in FIG. 6. Furthermore, the surface roughness Rz of less than 0.8 μm would be achieved across a wider range of concentration levels and conditions, including those shown in FIGS. 5 and 6.

In such an instance, the silicon oxide film 70 would be left on the top layer of the base surface 2a of the recess 2. However, the surface roughness Rz would not be affected by this. The silicon oxide film 70, which is left on the top layer of the base surface 2a, can be etched and removed at the time of removing the etching mask 60.

In the example shown in FIG. 2, the anodizing process is performed while the voltage is applied from the direct current power source 210. In place of the direct current power source 210, a potentiostat may be used in a method that uses three electrodes, which includes the reference electrode.

Furthermore, the main surface of the silicon substrate etched according to the present invention may have a surface orientation other than the (110).

Furthermore, the application of the present invention is not limited to the pressure sensor and may include etching of the silicon substrate in the KOH solution in a manufacturing process of, for example, an acceleration sensor, a gas sensor, or a flow sensor.

Additional advantages and modifications will readily occur to those skilled in the art. The invention in its broader terms is therefore not limited to the specific details, representative apparatus, and illustrative examples shown and described.

What is claimed is:

1. A method for etching a semiconductor substrate by immersing the semiconductor substrate in etching solution, the method comprising:
immersing a silicon substrate, which is the semiconductor substrate, in potassium hydroxide solution, which is the etching solution;
anodizing a main surface of the silicon substrate, which is immersed in the potassium hydroxide solution, by applying an electrical potential to the silicon substrate while the silicon substrate is used as an anode, so that an oxide film is formed in the main surface of the silicon substrate; and
etching a main surface side of the silicon substrate in the potassium hydroxide solution.

2. The method according to claim 1, wherein the etching of the main surface side of the silicon substrate includes etching of the main surface side of the silicon substrate without applying the electrical potential to the silicon substrate upon initiation of the etching of the main surface side of the silicon substrate.

3. The method according to claim 1, wherein the etching of the main surface side of the silicon substrate includes etching of the main surface side of the silicon substrate while applying the electrical potential, which causes formation of the oxide film, to the silicon substrate.

4. The method according to claim 1, wherein the etching of the main surface side of the silicon substrate includes maintaining a KOH concentration of the potassium hydroxide solution in a range of 39-48 weight percent and also maintaining the solution temperature of the potassium hydroxide solution in a range of 90-140 degrees Celsius.

5. The method according to claim 1, wherein the main surface of the silicon substrate has a (110) surface.
